(19) United States
(12) Patent Application Publication
(10) Pub. No.: US 2016/0351843 A1
(43) Pub. Date: Dec. 1, 2016

(54) QUANTUM DOT LIGHT EMITTING DIODES DISPLAY

(71) Applicant: SHENXZHEN CHINA STAR OPTOELECTRONICS TECHNOLOGY CO LTD., Shenzhen, Guangming (CN)

(72) Inventors: Qingdou YANG, Shenzhen, Guangdong (CN); Yawei LIU, Shenzhen, Guangdong (CN)

(21) Appl. No.: 14/771,014

(22) PCT Filed: May 13, 2015
(86) PCT No.: PCT/CN2015/078833

§ 371 Date: Aug. 27, 2015

(30) Foreign Application Priority Data
May 7, 2015 (CN) 201510230417.1

(51) Int. Cl. H01L 51/50; C09K 11/08; H01L 51/00; C09K 11/02; H01L 27/32; H01L 51/52

(52) U.S. Cl. CPC H01L 51/502; H01L 27/3211; H01L 51/5088; H01L 51/5056; H01L 51/5072; H01L 51/5253; H01L 27/3213; H01L 27/3244; H01L 51/0037; H01L 51/0081; H01L 51/0059; H01L 51/0035; H01L 51/0072; C09K 11/025; H01L 51/0067; C09K 11/08

(57) ABSTRACT

A quantum dot light emitting diodes display is provided. The quantum dot light emitting diodes display comprises a first electrode, a hole injection layer, a hole transmission layer, a quantum dot light emitting layer, an electron transporting layer, and a second electrode. The quantum dot light emitting layer comprises a plurality of pixel units including red sub-pixels, green sub-pixels, and blue sub-pixels. At least one color of the sub-pixels of the pixel units is formed by mixing at least two quantum dots with different peak emission wavelengths corresponding to different colors.

### FIELD OF THE INVENTION

The present invention relates to the field of display technologies, and more particularly, to a quantum dot light emitting diodes display.

### BACKGROUND OF THE INVENTION

A single sub-pixel of a pixel unit of a quantum dot light emitting diodes display is composed of a quantum dot. For example, a red sub-pixel is composed of a single red light quantum dot, a green sub-pixel is composed of a single green light quantum dot, and a blue sub-pixel is composed of a single blue light quantum dot, for increasing brightness and vividness of the display and reducing power consumption. The quantum dot light emitting diodes have advantages relative to organic light emitting diodes such as: quantum dot light emitting diodes have a narrower half peak width, a higher color purity of the display, longer lifetime, and a higher external quantum efficiency which may reach 100%. Furthermore, the quantum dot light emitting diodes can emit infrared light, and the organic light emitting diodes cannot emit infrared light.

Since each of the red color organic material, green color organic material, and blue color organic material has a different degradation lifetime, respectively, the color of OLEDs display will change over time. The sub-pixel of the conventional display manufactured by quantum dot light emitting diodes is composed of different sizes of quantum dot synthesized from the same material. Because of the quantum confinement effect, red color, green color, and blue emitting light is realized. Although the quantum dot synthesized from the same material have similar degradation lifetimes, the half peak width of the quantum dot light emitting diodes is narrower. Thus, the light is insufficiently soft so that human eye feels fatigued easily.

Therefore, it is necessary to provide a quantum dot light emitting diodes display to solve the above problems.

### SUMMARY OF THE INVENTION

An object of the present invention is to provide a quantum dot light emitting diodes display which can solve a technical problem of the quantum dots of the sub-pixel of a conventional quantum dot light emitting diodes synthesized by a single material, the light is insufficiently soft so that human eye feels fatigued easily.

In order to solve the aforementioned drawbacks of the prior art, the present invention provides a quantum dot light emitting diodes display comprising:

a base substrate;

a switch array layer disposed on the base substrate, the switch array layer includes a plurality of thin film transistors;

a first electrode disposed on the switch array layer;

a hole injection layer disposed on the first electrode;

a hole transmission layer disposed on the hole injection layer;

a quantum dot light emitting layer disposed on the hole transmission layer, the quantum dot light emitting layer comprises a plurality of pixel units including red sub-pixels, green sub-pixels, and blue sub-pixels, each sub-pixel of the pixel unit is driven by one of the thin film transistors;

an electron transporting layer disposed on the quantum dot light emitting layer;

a second electrode disposed on the electron transporting layer; and an encapsulation layer disposed on the second electrode, the encapsulation layer is bonded with the base substrate by an adhesive;

wherein at least one color of the sub-pixels of the red sub-pixels, the green sub-pixels, and the blue sub-pixels is formed by mixing at least two quantum dots with different peak emission wavelengths corresponding to different colors.

In the quantum dot light emitting diodes display described above, the pixel units further comprise white sub-pixels which are formed by mixing at least two white light quantum dots having two different peak emission wavelengths.

In the quantum dot light emitting diodes display described above, the pixel units further comprise white sub-pixels which are formed by mixing red light quantum dots, green light quantum dots, and blue light quantum dots.

In the quantum dot light emitting diodes display described above, a material of the hole injection layer is polyethylene dioxythiophene.

In the quantum dot light emitting diodes display described above, a material of the electron transporting layer is 8-Hydroxyquinoline aluminum.

In the quantum dot light emitting diodes display described above, a material of the hole transmission layer is polytriphenylamine.

In the quantum dot light emitting diodes display described above, a protective layer is disposed between the encapsulation layer and the second electrode.

In the quantum dot light emitting diodes display described above, all of the red sub-pixels, green sub-pixels, blue sub-pixels, and white sub-pixels are formed by mixing organic host materials with quantum dots.

In the quantum dot light emitting diodes display described above, the organic host materials are TCTA (4,4′,4″-Tri(9-carbazoyl)triphenyla).

In the quantum dot light emitting diodes display described above, the organic host materials are TRZ (1,2,4-triazolat).

In order to solve the aforementioned drawbacks of the prior art, the present invention provides a quantum dot light emitting diodes display comprising:

a base substrate;

a first electrode disposed on the switch array layer;

a hole injection layer disposed on the first electrode;

a hole transmission layer disposed on the hole injection layer;

a quantum dot light emitting layer disposed on the hole transmission layer, the quantum dot light emitting layer comprises a plurality of pixel units including red sub-pixels, green sub-pixels, and blue sub-pixels;

an electron transporting layer disposed on the quantum dot light emitting layer; and

a second electrode disposed on the electron transporting layer;

wherein at least one color of the sub-pixels of the red sub-pixels, the green sub-pixels, and the blue sub-pixels is formed by mixing at least two quantum dots having different peak emission wavelengths corresponding to different colors.

In the quantum dot light emitting diodes display described above, the pixel units further comprise white sub-pixels which are formed by mixing at least two white light quantum dots having two different peak emission wavelengths.

In the quantum dot light emitting diodes display described above, the pixel units further comprise white sub-pixels which are formed by mixing the red light quantum dots, the green light quantum dots, and the blue light quantum dots.

In the quantum dot light emitting diodes display described above, the pixel units further comprise white sub-pixels which are formed by mixing the blue light quantum dots with yellow light quantum dots.

In the quantum dot light emitting diodes display described above, the red sub-pixels are formed by mixing at least two red light quantum dots having two different peak emission wavelengths;

the green sub-pixels are formed by mixing at least two green light quantum dots having two different peak emission wavelengths; and

the blue sub-pixels are formed by mixing at least two blue light quantum dots having two different peak emission wavelengths.

In the quantum dot light emitting diodes display described above, at least one color of the sub-pixels of the red sub-pixels, the green sub-pixels, and the blue sub-pixels is formed by mixing at least two constituent materials of quantum dots with corresponding colors.

In the quantum dot light emitting diodes display described above, at least one color of the sub-pixels of the red sub-pixels, the green sub-pixels, and the blue sub-pixels is formed by mixing at least two particle sizes of quantum dots with corresponding colors.

In the quantum dot light emitting diodes display described above, a material of the base substrate is a glass or a flexible material.

In the quantum dot light emitting diodes display described above, the quantum dot light emitting diodes display further comprises a switch array layer including a plurality of thin film transistors, and each sub-pixel of the pixel unit is driven by one of the thin film transistors.

In the quantum dot light emitting diodes display described above, the quantum dot light emitting diodes display further comprises an encapsulation layer which is bonded with the base substrate by an adhesive.

The quantum dot light emitting diodes display can increase the half peak width of the sub-pixel through at least one color of the sub-pixels which is formed by mixing at least two quantum dots corresponding to different colors for softening the light from the display and easing visual fatigue.

### DESCRIPTION OF THE DRAWINGS

FIG. 1 is a structural schematic view of a quantum dot light emitting diodes display according to a first embodiment of the present invention;

FIG. 2 is a structural schematic view of the quantum dot light emitting diodes display according to a second embodiment of the present invention;

FIG. 3 is a schematic view of peak emission wavelengths of green light quantum dots of the present invention;

FIG. 4 is a schematic view of peak emission wavelengths of red light quantum dots of the present invention;

FIG. 5 is a schematic view of peak emission wavelengths of blue light quantum dots of the present invention;

FIG. 6 is a schematic view of the first arrangement of a pixel unit of the present invention; and

FIG. 7 is a schematic view of the second arrangement of a pixel unit of the present invention.

### DETAILED DESCRIPTION OF THE PREFERRED EMBODIMENTS

This description of the exemplary embodiments is intended to be read in connection with the accompanying drawings, which are to be considered part of the entire written description. In the description, terms such as “lower,” “upper,” “horizontal,” “vertical,”, “above,” “below,” “up,” “down,” “top”, and “bottom” as well as derivatives thereof should be construed to refer to the orientation as then described or as shown in the drawing under discussion. These terms are for convenience of description and do not require that the apparatus be constructed or operated in a particular orientation, and do not limit the scope of the invention.

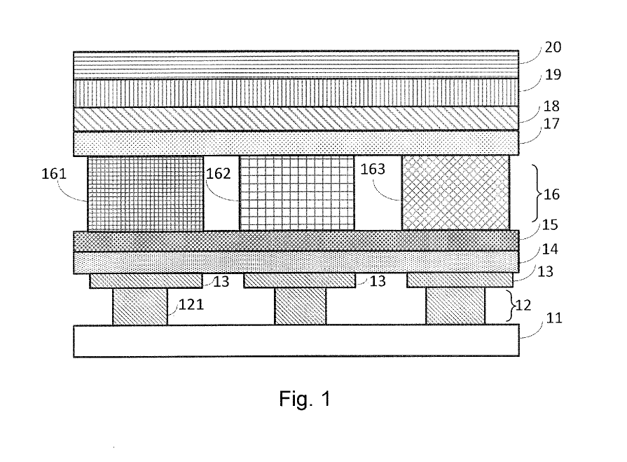

Refer to FIG. 1, which is a structural schematic view of a quantum dot light emitting diodes display according to a first embodiment of the present invention.

A quantum dot light emitting diodes display of the present invention comprises a base substrate 11, a first electrode 13, a hole injection layer 14, a hole transmission layer 15, a quantum dot light emitting layer 16, an electron transporting layer 17, and a second electrode 18. The first electrode is disposed on the base substrate 11. The first electrode 13 can be a negative electrode. The hole injection layer 14 is disposed on the first electrode 13. The hole transmission layer 15 is disposed on the hole injection layer 14. The quantum dot light emitting layer 16 is disposed on the hole transmission layer 15. The electron transporting layer 17 is disposed on the quantum dot light emitting layer 16. The second electrode 18 is disposed on the electron transporting layer 17, which can be a positive electrode.

The quantum dot light emitting layer 16 comprises a plurality of pixel units including red sub-pixels 161, green sub-pixels 162, and blue sub-pixels 163.

At least one color of the red sub-pixels 161, the green sub-pixels 162, and the blue sub-pixels 163 is formed by mixing at least two quantum dots with different peak emission wavelengths corresponding to different colors.

Namely, the red sub-pixels 161 are formed by mixing at least two red light quantum dots having two different peak emission wavelengths, the green sub-pixels 162 are formed by mixing at least two white green quantum dots having two different peak emission wavelengths, and the blue sub-pixels 163 are formed by mixing at least two blue light quantum dots having two different peak emission wavelengths.

In the preferred embodiment of the present invention, each of the red sub-pixels 161, the green sub-pixels 162, and the blue sub-pixels 163 is formed by mixing quantum dots having different peak emission wavelengths corresponding to different colors. The red sub-pixels 161 composed of a variety kinds of quantum dots are located within a red light band, the green sub-pixels 162 composed of a variety kinds of quantum dots are located within a green light band, and the blue sub-pixels 163 composed of a variety kinds of quantum dots are located within a blue light band. For example, a wavelength range of a blue light is 440 nm-480 nm. Then, the blue sub-pixels of the pixel unit can be formed by mixing a blue light quantum dot having the peak emission wavelength of 450 nm and another blue light quantum dot having the peak emission wavelength of 465 nm for jointly emitting. Certainly, the blue sub-pixels can be formed by mixing two or more kinds of blue light quantum dots.

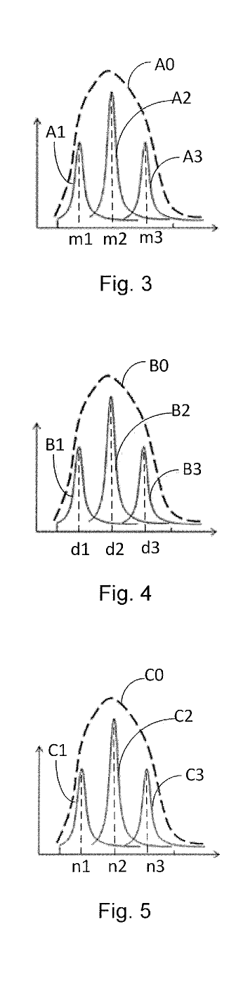

Further combine FIG. 1 with FIG. 3, an x-coordinate represents a length of the wavelength (an x-coordinate shown in FIG. 4 and FIG. 5 also represents the length of the wavelength). A1, A2, and A3 represent three kinds of the red light quantum dots with different peak emission wavelengths. The peak emission wavelength of A1 is m1, the peak emission wavelength of A2 is m2, and the peak emission wavelength of A3 is m3. The red sub-pixels of the pixel unit are formed by mixing three kinds of the red light quantum dots A1, A2, and A3. A red light emitted from the red sub-pixels formed by mixing three kinds of the red light quantum dots corresponds to a curve A0 shown in FIG. 3. A half peak width of the red sub-pixels is significantly greater than the half peak width of the single red light quantum dots A1, A2, or A3. Namely, the half peak width can be effectively increased through adopting mixing at least two kinds of quantum dots having different peak emission wavelengths. Furthermore, a wavelength range of the red light A0 emitted from the red sub-pixels is preferably 620 nm-760 nm.

For the same reason, combine FIG. 1 with FIG. 4, B1, B2, and B3 represent three kinds of the green light quantum dots with different peak emission wavelengths. The peak emission wavelength of B1 is d1, the peak emission wavelength of B2 is d2, and the peak emission wavelength of B3 is d3. The green sub-pixels of the pixel unit are formed by mixing three kinds of the green light quantum dots B1, B2, and B3. A green light emitted from the green sub-pixels formed by mixing three kinds of the green light quantum dots corresponds to a curve BO shown in FIG. 4. A half peak width of the green sub-pixels is significantly greater than the half peak width of the single green light quantum dots B1, B2, or B3. Furthermore, a wavelength range of the green light B0 emitted from the red sub-pixels is preferably 500 nm-578 nm.

For the same reason, combine FIG. 1 with FIG. 5, C1, C2, and C3 represent three kinds of the blue light quantum dots with different peak emission wavelengths. The peak emission wavelength of C1 is n1, the peak emission wavelength of C2 is n2, and the peak emission wavelength of C3 is n3. The blue sub-pixels of the pixel unit are formed by mixing three kinds of the blue n light quantum dots C1, C2, and C3. A blue light emitted from the blue sub-pixels formed by mixing three kinds of the blue light quantum dots corresponds to a curve CO shown in FIG. 5. A half peak width of the blue sub-pixels is significantly greater than the half peak width of the single blue light quantum dots C1, C2, or C3. Furthermore, a wavelength range of the blue light CO emitted from the red sub-pixels is preferably 446 nm-464 nm.

In the prior art, a red sub-pixel is composed of a single red light quantum dot, a green sub-pixel is composed of a single green light quantum dot, and a blue sub-pixel is composed of a single blue light quantum dot. Instead, at least one color of the sub-pixels of the pixel unit is formed by mixing two or more kinds of quantum dots with different peak emission wavelengths. Thus, the half peak width of the sub-pixel is wider. Since the sub-pixel is wider, the light is softer. The quantum dot light emitting diodes display can soften the light from the display and ease visual fatigue effectively.

As shown in FIG. 1, the quantum dot light emitting diodes display further comprises a switch array layer 12 preferably disposed on the base substrate 11. The first electrode 13 is disposed on the switch array layer 12. The switch array layer 12 includes a plurality of thin film transistors, each sub-pixel of the pixel unit is driven by one of the thin film transistors. For example, each of the red sub-pixel 161, the green sub-pixel 162, and the blue sub-pixel 163 is driven by one of the thin film transistors.

A material of the hole transmission layer 15 is polytriphenylamine. A material of the electron transporting layer 17 is 8-Hydroxyquinoline aluminum. A material of the hole injection layer 14 is polyethylene dioxythiophene. A material of the base substrate 11 is a glass or a flexible material.

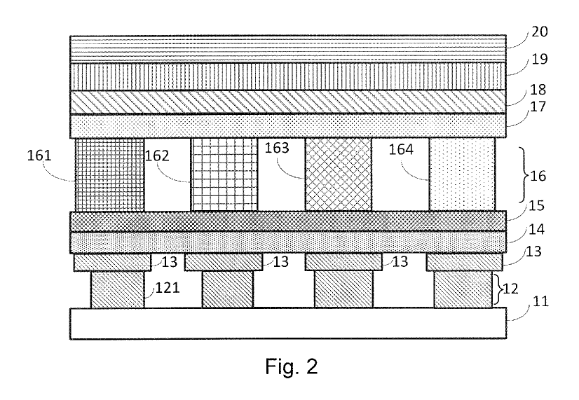

Referring to FIG. 1 and FIG. 2, the pixel units further comprise white sub-pixels 164. There are several ways to constitute the white sub-pixels 164, such as the white sub-pixels 164 are formed by mixing at least two white light quantum dots having two different peak emission wavelengths. The white sub-pixels 164 also can be formed by mixing red light quantum dots, green light quantum dots, and blue light quantum dots. The white sub-pixels 164 further can be formed by mixing blue light quantum dots with yellow light quantum dots. The pixel unit further comprises the yellow light quantum dots. The yellow light quantum dots are formed by mixing at least two yellow light quantum dots having two different peak emission wavelengths. The brightness of the white screen of the display can be increased, and the energy consumption of the display can be reduced through increasing the white sub-pixel.

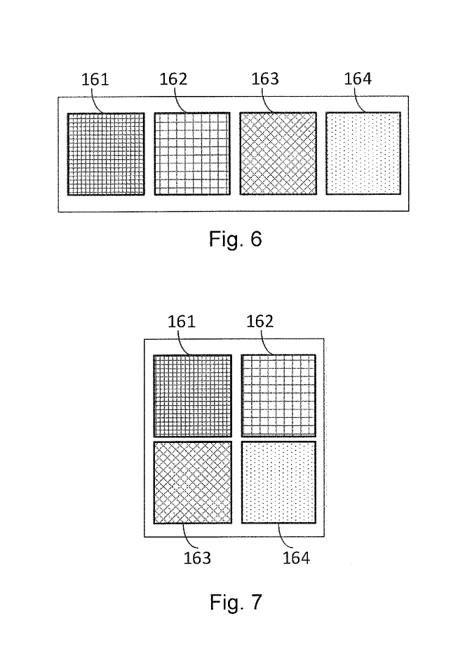

The sub-pixels of the pixel unit have a variety of arrangements. The embodiment of the present invention is only an example, and not a limitation. All sub-pixels of the pixel unit can be arranged side by side. For example, the red sub-pixels 161, the green sub-pixels 162, and the blue sub-pixels 163 of the pixel unit are arranged in a side-by-side arrangement. Alternatively, refer to FIG. 6, the red sub-pixels 161, the green sub-pixels 162, the blue sub-pixels 163, and the white sub-pixels 164 of the pixel unit are arranged in a side by side arrangement. Alternatively, refer to FIG. 7, the red sub-pixels 161, the green sub-pixels 162, the blue sub-pixels 163, and the white sub-pixels 164 of the pixel unit are arranged in a quartet arrangement. Preferably, the red sub-pixel 161 is in the upper left corner, the green sub-pixel 162 is in the upper right corner, the blue sub-pixel 163 is in the lower left corner, and the white sub-pixel 164 is in the lower right corner.

Referring to FIG. 1 and FIG. 2, the quantum dot light emitting diodes display further comprises an encapsulation layer 20 which is bonded with the base substrate 11 by an adhesive for sealing and protecting internal electronic components. A protective layer 19 is disposed between the encapsulation layer 20 and the second electrode 18. The protective layer 19 is composed of nitrogen or a transparent layer having a desiccant for preventing moisture or oxygen from entering into the display.

One of the base substrate 11 and the encapsulation layer 20 has an ability of transmittance. A material of the encapsulation layer 20 is a glass or a flexible material.

The red sub-pixels 161, the green sub-pixels 162, the blue sub-pixels 163, and the white sub-pixels 164 are formed by mixing organic host materials with quantum dots. Specifically, the organic host materials, inorganic quantum dots, and a solvent are mixed. A mixed solution is coated on the hole transmission layer. Then, after the mixed solution volatilizes, the solvent is removed from the mixed solution for obtaining the sub-pixel. The organic host materials adapted in the manufacturing process may include, but are not limited to, TCTA (4,4′,4″-Tri(9-carbazoyl)triphenyla) and/or TRZ (1,2,4-triazolat). The structural formula of the TCTA (4,4′,4″-Tri(9-carbazoyl)triphenyla) is as follows.

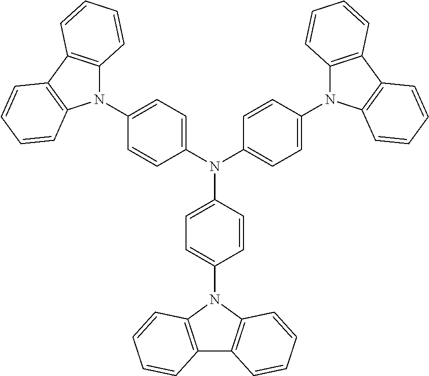 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

The structural formula of the TRZ (1,2,4-triazolat) is as follows.

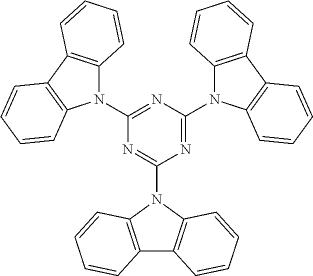 [SMILES: c1ccc2c(c1)c1ccccc1n2-c1nc(-n2c3ccccc3c3ccccc32)nc(-n2c3ccccc3c3ccccc32)n1]

The red sub-pixels 161, the green sub-pixels 162, the blue sub-pixels 163, and the white sub-pixels 164 can also be an inorganic quantum dots layer which is not formed by the organic host materials. Besides, at least one color of the sub-pixels is formed by mixing at least two quantum dots with different peak emission wavelengths corresponding to different colors. The manufacturing method comprises: a variety of inorganic quantum dots is mixed with a surface coating agent and the solvent, and a mixed solution is coated on the hole transmission layer. Then, after the mixed solution volatilizes, the solvent is removed from the mixed solution for obtaining the sub-pixel. The surface coating agent can be selected from the group consisting of stearic acid, phosphine oxide zinc, or polymethyl methacrylate.

Since the quantum dots belong to nanoparticles and zero-dimensional material, an agglomeration effect tends to occur and leads to oxidation and fluorescence quenching. Therefore, the manufacturing process for manufacturing the sub-pixels needs to use the organic host materials or the surface coating agent to prevent the agglomeration effect and oxidation of the quantum dots.

In the present invention, at least one color of the sub-pixels is formed by mixing at least two quantum dots with different peak emission wavelengths corresponding to different colors. It includes the following two embodiments.

(1) At least one color of the sub-pixels is formed by mixing two or more different kinds (that is two or more different materials) of the quantum dots. For example, the blue sub-pixels can be formed by mixing two or more different kinds of the blue quantum dots, such as mixing zinc cadmium sulfide quantum dots (ZnCdS quantum dots) with CdSe/ZnS quantum dots, for emitting the blue light.

(2) At least one color of the sub-pixels is formed by mixing at least two particle sizes of the same kind of the quantum dots. For example, the blue sub-pixels can be formed by mixing two or more different particle sizes of the blue quantum dots, such as CdSe/ZnS quantum dots, for emitting the blue light.

It can be understood that the red sub-pixels and the green sub-pixels are obtained by mixing the quantum dots with corresponding colors through the manufacturing process of the two embodiments.

The white light quantum dots can be II˜VI group quantum dots, such as CdSe (cadmium selenide) quantum dots, CdS (cadmium sulfide) quantum dots, CdTe (cadmium telluride) quantum dots, CdMnS (cadmium, manganese sulfur) quantum dots, ZnSe (zinc selenide) quantum dots, or ZnMnSe (zinc-manganese selenium) quantum dots.

The blue light quantum dots can be ZnCdS (zinc cadmium sulfide) quantum dots, CdSe/ZnS quantum dots or SiN4 quantum dots.

The green light quantum dots can be CdSe/ZnS quantum dots, or ZnSe: Cu2+quantum dots.

The red light quantum dots can be CdSe/CdS/ZnS quantum dots.

The yellow light quantum dots can be CdSe/CdS/ZnS quantum dots, or ZnS: Mn2+quantum dots.

The quantum dot light emitting diodes display of the present invention can increase the half peak width of the sub-pixel through at least one color of the sub-pixels being formed by mixing at least two quantum dots corresponding to different colors for softening the light from the display and easing visual fatigue. The application of quantum dot light emitting technology can improve the stability and efficiency of the display. A spectral chromaticity coordinate of each sub-pixel can be adjusted through controlling the particle size and the composition of the quantum dot within the sub-pixel. A light emitting layer of the quantum dot of the present invention is only several hundred nanometers in thickness which is more easily fabricated on a flexible substrate than the conventional LCD/LED. Therefore, the present invention can achieve the advantages of ultra-thin, transparent and easy bending of the display.

As described above, the present invention has been described with preferred embodiments thereof, and it is understood that many changes and modifications to the described embodiments can be carried out without departing from the scope and the spirit of the invention that is intended to be limited only by the appended claims.

What is claimed is:

1. A quantum dot light emitting diodes display, comprising:
a base substrate;
a switch array layer, disposed on the base substrate, comprising a plurality of thin film transistors;
a first electrode, disposed on the switch array layer;
a hole injection layer, disposed on the first electrode;
a hole transmission layer, disposed on the hole injection layer;
a quantum dot light emitting layer, disposed on the hole transmission layer, comprising a plurality of pixel units including red sub-pixels, green sub-pixels, and blue sub-pixels, each sub-pixel of the pixel unit being driven by one of the thin film transistors;
an electron transporting layer, disposed on the quantum dot light emitting layer;
a second electrode, disposed on the electron transporting layer; and
an encapsulation layer, disposed on the second electrode and bonded with the base substrate by an adhesive;
wherein at least one color of the sub-pixels of the red sub-pixels, the green sub-pixels, and the blue sub-pixels is formed by mixing at least two quantum dots having different peak emission wavelengths corresponding to the color.

2. The quantum dot light emitting diodes display according to claim 1, wherein the pixel units further comprise white sub-pixels which are formed by mixing at least two white light quantum dots having two different peak emission wavelengths.

3. The quantum dot light emitting diodes display according to claim 1, wherein the pixel units further comprise white sub-pixels which are formed by mixing red light quantum dots, green light quantum dots, and blue light quantum dots.

4. The quantum dot light emitting diodes display according to claim 1, wherein a material of the hole injection layer is polyethylene dioxythiophene.

5. The quantum dot light emitting diodes display according to claim 1, wherein a material of the electron transporting layer is 8-Hydroxyquinoline aluminum.

6. The quantum dot light emitting diodes display according to claim 1, wherein a material of the hole transmission layer is polytriphenylamine.

7. The quantum dot light emitting diodes display according to claim 1, wherein a protective layer is disposed between the encapsulation layer and the second electrode.

8. The quantum dot light emitting diodes display according to claim 1, wherein all of the red sub-pixels, green sub-pixels, blue sub-pixels, and white sub-pixels are formed by mixing organic host materials with quantum dots.

9. The quantum dot light emitting diodes display according to claim 8, wherein the organic host materials include TCTA (4,4′,4″-Tri(9-carbazoyl)triphenyla).

10. The quantum dot light emitting diodes display according to claim 8, wherein the organic host materials include TRZ (1,2,4-triazolat).

11. A quantum dot light emitting diodes display, comprising:
a base substrate;
a first electrode disposed on the switch array layer;
a hole injection layer disposed on the first electrode;
a hole transmission layer disposed on the hole injection layer;
a quantum dot light emitting layer disposed on the hole transmission layer, the quantum dot light emitting layer comprises a plurality of pixel units including red sub-pixels, green sub-pixels, and blue sub-pixels;
an electron transporting layer disposed on the quantum dot light emitting layer; and
a second electrode disposed on the electron transporting layer;
wherein at least one color of the sub-pixels of the red sub-pixels, the green sub-pixels, and the blue sub-pixels is formed by mixing at least two quantum dots having different peak emission wavelengths corresponding to the color.

12. The quantum dot light emitting diodes display according to claim 11, wherein the pixel units further comprise white sub-pixels which are formed by mixing at least two white light quantum dots having two different peak emission wavelengths.

13. The quantum dot light emitting diodes display according to claim 11, wherein the pixel units further comprise white sub-pixels which are formed by mixing the red light quantum dots, the green light quantum dots, and the blue light quantum dots.

14. The quantum dot light emitting diodes display according to claim 11, wherein the pixel units further comprise white sub-pixels which are formed by mixing the blue light quantum dots with yellow light quantum dots.

15. The quantum dot light emitting diodes display according to claim 11, wherein the red sub-pixels are formed by mixing at least two red light quantum dots having two different peak emission wavelengths;
the green sub-pixels are formed by mixing at least two green light quantum dots having two different peak emission wavelengths; and
the blue sub-pixels are formed by mixing at least two blue light quantum dots having two different peak emission wavelengths.

16. The quantum dot light emitting diodes display according to claim 11, wherein at least one color of the sub-pixels of the red sub-pixels, the green sub-pixels, and the blue sub-pixels is formed by mixing at least two constituent materials of quantum dots which are corresponding to the color.

17. The quantum dot light emitting diodes display according to claim 11, wherein at least one color of the sub-pixels of the red sub-pixels, the green sub-pixels, and the blue sub-pixels is formed by mixing at least two particle sizes of quantum dots with corresponding colors.

18. The quantum dot light emitting diodes display according to claim 11, wherein a material of the base substrate is a glass or a flexible material.

19. The quantum dot light emitting diodes display according to claim 11, wherein the quantum dot light emitting diodes display further comprises a switch array layer including a plurality of thin film transistors, and each sub-pixel of the pixel unit is driven by one of the thin film transistors.

20. The quantum dot light emitting diodes display according to claim 11, wherein the quantum dot light emitting diodes display further comprises an encapsulation layer which is bonded with the base substrate by an adhesive.
